(19) United States
(12) Patent Application Publication
(10) Pub. No.: US 2025/0151458 A1
(43) Pub. Date: May 8, 2025

(54) MONOLITHIC RGB MICROLED ARRAY

(71) Applicant: Snap Inc., Santa Monica, CA (US)

(72) Inventors: Peng Feng, Sheffield (GB); Jack Haggar, Sheffield (GB); Kean Boon Lee, Sheffield (GB); Nicolas Poyiatzis, Sheffield (GB); Ye Tian, Sheffield (GB); Xiang Yu, Sheffield (GB)

(21) Appl. No.: 18/926,428

(22) Filed: Oct. 25, 2024

Related U.S. Application Data
(60) Provisional application No. 63/596,187, filed on Nov. 3, 2023.

(51) Int. Cl. H01L 33/00; H01L 27/15; H01L 33/06; H01L 33/08; H01L 33/20; H01L 33/32

(52) U.S. Cl. CPC H10H 20/0137; H10H 20/81; H10H 20/812; H10H 20/813; H10H 20/819; H10H 20/825; H10H 29/10

(57) ABSTRACT

A light emitting diode (LED) pixel array and method of fabrication thereof. A semiconductor wafer template includes a dielectric layer formed over a lower n-type gallium nitride (n-GaN) layer. A first aperture and a second aperture are formed through the dielectric layer and extending to the lower n-GaN layer, the second aperture being narrower than the first aperture. A mesa is formed within the first aperture by successively forming a mesa n-GaN layer, a mesa MQW layer above the mesa n-GaN layer, and a mesa p-GaN layer above the mesa MQW layer. A pyramid having sidewalls is formed within the second aperture by successively forming a pyramidal n-GaN layer, a pyramidal MQW layer, and a pyramidal p-GaN layer. The mesa n-GaN layer, mesa MQW layer, and mesa p-GaN layer form a mesa LED. The pyramidal n-GaN layer, pyramidal MQW layer, and pyramidal p-GaN layer form a pyramid LED.

### CLAIM OF PRIORITY

This application claims the benefit of priority to U.S. Provisional Application Ser. No. 63/596,187, filed on Nov. 3, 2023, which is incorporated herein by reference in its entirety.

### TECHNICAL FIELD

The present disclosure relates generally to light emitting diode (LED) fabrication and more particularly to fabrication of monolithic red/green/blue microLED pixel arrays.

### BACKGROUND

Group III-nitride LEDs, grown on a micrometer scale, are referred to as micro-sized LEDs or simply microLEDs, micro-LEDs, or LEDs. Typically, the diameter of a μLED is 50 micrometers or less. μLEDs are expected to provide the basis for new generation displays and visible light communication (VLC) applications. III-nitride μLEDs exhibit a number of unique features for display applications compared with organic light-emitting diodes (OLEDs) and liquid crystal displays (LCDs). Unlike LCDs, III-nitride micro-displays using μLEDs are self-emissive. Monochromatic displays using μLEDs typically exhibit high resolution, high efficiency, and high contrast ratio. OLEDs are typically operated at a current density that is several orders of magnitude lower than semiconductor LEDs in order to maintain a reasonable lifetime. As a consequence, the luminance of OLEDs is low relative to III-nitride μLEDs. Furthermore, III-nitride μLEDs intrinsically exhibit long operation lifetime and chemical robustness in comparison with OLEDs. Therefore, it is expected that III-nitride μLEDs could potentially replace LCDs and OLEDs for high resolution and high brightness displays in a wide range of applications, such as smart phones, in the near future.

### BRIEF DESCRIPTION OF THE SEVERAL VIEWS OF THE DRAWINGS

In the drawings, which are not necessarily drawn to scale, like numerals may describe similar components in different views. To easily identify the discussion of any particular element or act, the most significant digit or digits in a reference number refer to the figure number in which that element is first introduced. Some non-limiting examples are illustrated in the figures of the accompanying drawings in which:

FIG. 1 illustrates operations of an example method for fabricating an LED pixel array, according to some examples.

FIG. 2 illustrates a cross-sectional view of a first example semiconductor wafer template, according to some examples.

FIG. 3 illustrates a cross-sectional view of the semiconductor wafer template of FIG. 2 after a first LED pixel array fabrication operation, according to some examples.

FIG. 4 illustrates a cross-sectional view of the semiconductor wafer template of FIG. 2 after a further LED pixel array fabrication operation, according to some examples.

FIG. 5 illustrates four different orientations of surfaces formed through a hexagonal crystal structure, according to some examples.

FIG. 6 illustrates a cross-sectional view of the semiconductor wafer template of FIG. 2 after a further LED pixel array fabrication operation, according to some examples.

FIG. 7 illustrates a cross-sectional view of the semiconductor wafer template of FIG. 2 after a further LED pixel array fabrication operation, according to some examples.

FIG. 8 illustrates a cross-sectional view of the semiconductor wafer template of FIG. 2 after a further LED pixel array fabrication operation, according to some examples.

FIG. 9 illustrates a cross-sectional view of the semiconductor wafer template of FIG. 2 after a further LED pixel array fabrication operation, according to some examples.

FIG. 10 illustrates a cross-sectional view of the semiconductor wafer template of FIG. 2 after a further LED pixel array fabrication operation, according to some examples.

FIG. 11 illustrates an overhead view of an LED pixel structure according to FIG. 10, according to some examples.

### DETAILED DESCRIPTION

Examples of the present disclosure provide monolithic red-green-blue (RGB) LED pixels, LED pixel arrays, and methods for fabrication thereof. In some examples, an LED pixel structure (such as a microLED pixel structure) may be fabricated from a semiconductor wafer template to include an n-type gallium nitride (n-GaN) layer, as well as a mesa-shaped structure and a pyramidal structure formed above the n-GaN layer. The mesa includes a multiple quantum well (MQW) layer and a p-type GaN (p-GaN) layer, which form a mesa LED with the n-GaN layer. Similarly, the pyramid includes a MQW layer and a p-GaN layer, which form a pyramid LED with the n-GaN layer. Each LED may be configured as part of an LED to emit a single color of light, such as red light, green light, or blue light, or the LED may be configured to be tunable between two colors of light, such as a tunable blue/green or red/green LED. The LED pixel structure may be formed through epitaxy and etching techniques at a wafer scale, thereby forming an array of LED pixel structures.

In some examples, the MQW layer of the pyramid is deposited on semi-polar sidewalls of an n-GaN structure of the pyramid, thereby resulting in a relatively thin MQW layer within the pyramid having a relatively weak quantum confined stacking effect (QCSE); both of these factors may result in blue-shifting of the light emitted by the pyramid's MQW layer, making the pyramid LED suitable for use as a blue LED or a tunable blue/green LED. In some examples, furthermore, the amount of indium incorporated into the InGaN quantum wells of the pyramid's MQW layer may be relatively less than the MQW of the horizontal mesa top surface, further blue-shifting the pyramid LED relative to the mesa top LED. In some examples, the MQW layer of the mesa is deposited on a horizontal surface (e.g., a polar 0001 surface) of the mesa top, over a superlattice formed to reduce strain on the MQW layer during growth and thereby enhance the efficiency of the resulting mesa LED. Because red LEDs tend to be less efficient than LEDs configured to emit shorter wavelengths of light, the MQW layer grown on the mesa top may be configured to emit red light, with its efficiency enhanced by the use of a superlattice as the growth substrate. By providing a red LED grown on the strain-reducing superlattice over a relatively large area of the mesa top, the light emission of the red LED may be improved, as the strain relaxation provided by the superlattice allows incorporation of a greater amount of indium into the red MQW stack. In some examples, the mesa MQW layer may also be formed on semi-polar sidewalls of the mesa; the sidewall portions of the mesa MQW layer may be thinner than the top portion of the mesa MQW layer and/or may have weaker QCSE, resulting a blue shift in the light emitted by the sidewall portions. Thus, in some examples, a red LED may be formed using the top portion of the mesa MQW layer, and a green LED may be formed using the sidewall portions of the mesa MQW layer. In other examples, the entire mesa LED may be a red LED, a green LED, or a tunable red/green LED.

Accordingly, some examples described herein attempt to address one or more technical problems of microLED fabrication. By using epitaxial growth to fabricate an array of monolithic polychromatic microLEDs at wafer scale, some examples may avoid the need to stack and bond multiple wafers. In addition, some examples may avoid the damage to microLED sidewalls typically caused by etching in conventional microLED fabrication approaches, thereby potentially improving the performance of the LEDs.

As used herein, the “color” of an LED, multiple quantum well stack, or other light-emitting component may refer to a dominant or central wavelength of the light emitted by the component. The wavelengths of light emitted by a given LED can be controlled using various techniques, such as controlling the size of the LED and/or the structure, material composition, and/or size of the multiple quantum well stack of the LED.

Some examples described herein may use tunable multi-color LEDs, such as red/green LEDs or blue/green LEDs. Tunable multi-color LEDs can be fabricated using various techniques: for example, bluish-green light emissions from a blue/green LED, or reddish-green emissions from a red/green LED, can be achieved by exploiting the blueshift phenomenon, caused by the band-filling effect and the piezoelectric screening effect. In examples using a III-nitride LED, this blueshift phenomenon is unavoidable, but can be reduced by optimizing the LED epitaxy structure. For example, more quantum well (QW) layers can be grown to reduce the carrier density among each QW, V-pits can be formed on the MQW surface to increase the uniformity of current injection to each QW, and/or strain on the MQW can be reduced to reduce the piezoelectrical field. However, tunable LEDs described herein can exploit the blueshift phenomenon to enable modulation of the wavelength of the emitted light by modulating current injection, such that an increase in the injected current shifts the light wavelength toward shorter (bluer) wavelengths.

As used herein, terms such as “above”, “below”, “upper”, “lower”, and other relative vertical positions are intended in this disclosure to refer to the relative positions of various features with respect to a frame of reference in which a surface normal to a substrate surface used in semiconductor fabrication, such as a crystalline substrate surface, defines an upward direction. It will be appreciated that the portions of a fabricated semiconductor device farther from the substrate surface are referred to as “above” those portions closer to the substrate surface, even though the semiconductor device may be fabricated in contact with the substrate surface at any orientation relative to the Earth's gravitational field or any other frame of reference, and even though the semiconductor device may be used in any orientation after fabrication.

Other technical features and/or benefits may be readily apparent to one skilled in the art from the following figures, descriptions, and claims.

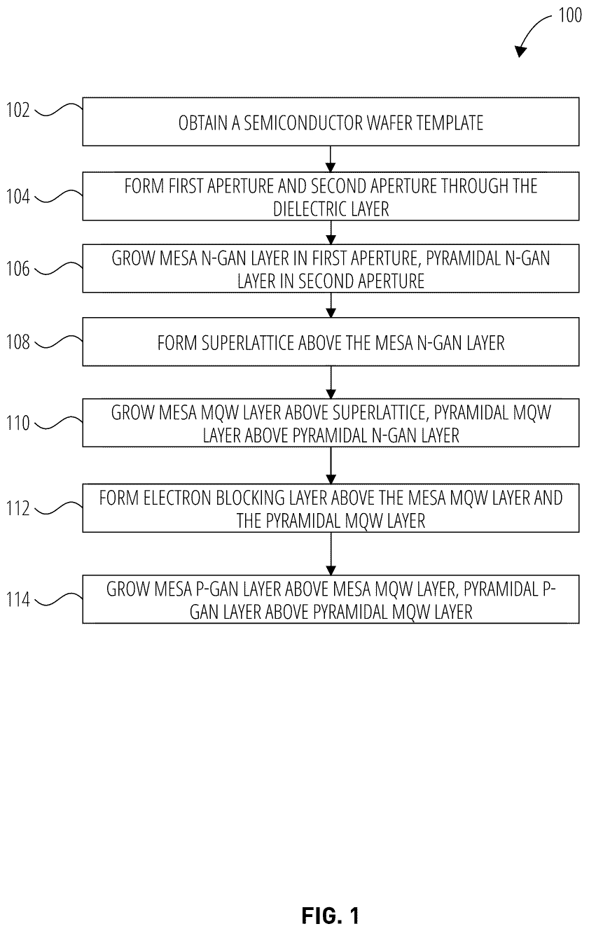

FIG. 1 illustrates an example method 100 for fabricating an LED pixel array. Although the example method 100 depicts a particular sequence of operations, the sequence may be altered without departing from the scope of the present disclosure. For example, some of the operations depicted may be performed in parallel or in a different sequence that does not materially affect the function of the method 100. In other examples, different components of an example device or system that implements the method 100 may perform functions at substantially the same time or in a specific sequence.

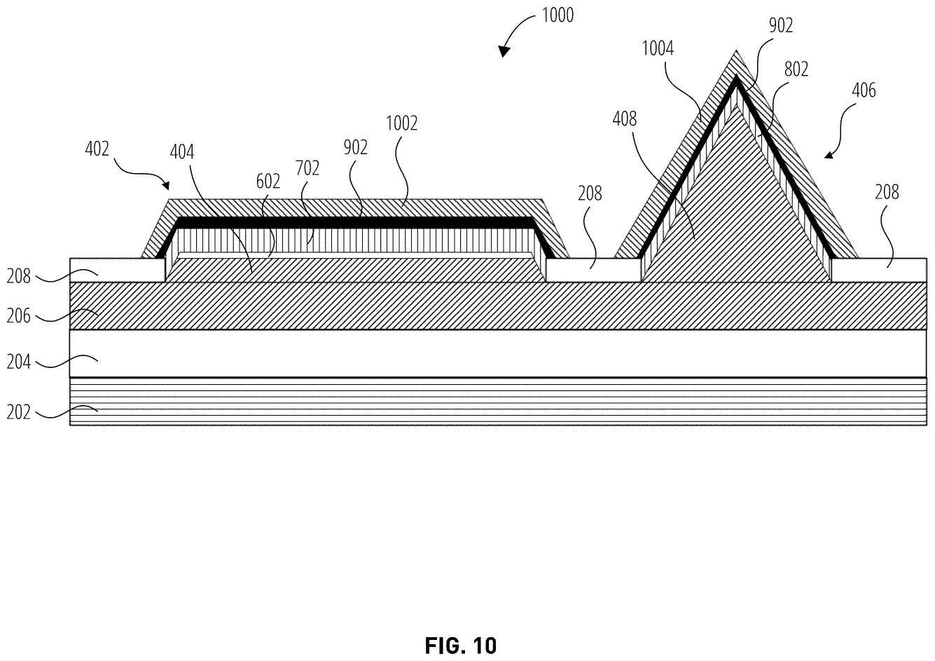

The example method 100 is described with reference to the fabrication of an example LED pixel structure, such as the pixel structure 1000 described below with reference to FIG. 10. It will be appreciated that, in other examples, the method 100 can be performed to fabricate devices having different structures or different characteristics from the example pixels and pixel arrays described herein. In some examples, the operations of method 100 may be performed at wafer scale to form a microLED pixel array, such that thousands or millions of LED pixel structures are formed within the wafer simultaneously. Epitaxial growth or overgrowth operations and other deposition operations may be performed using wafer-scale deposition techniques such as metal organic chemical vapor deposition (MOCVD), and selective etching operations may be performed using photolithography in combination with wet or dry etching at wafer scale or at least multi-pixel scale. In some examples, the semiconductor materials used in the method 100 include p-GaN and n-GaN materials, and only wet etching may be used in etching operations contacting p-GaN material or MQW stacks, so as to prevent damage to the p-GaN structure caused by dry etching.

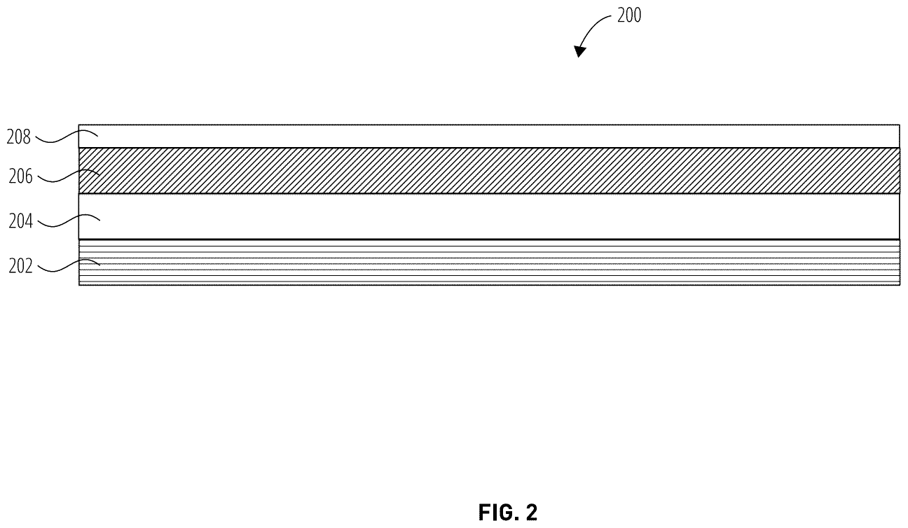

The example method 100 is described below with reference to example LED pixel array fabrication operations performed on a first example semiconductor wafer template 200, described below with reference to FIG. 2 through FIG. 10. It will be appreciated that, in other examples, the method 100 can be performed using operations that differ from the example operations and structures as illustrated and described.

According to some examples, the method 100 includes obtaining a semiconductor wafer template at operation 102. An example semiconductor wafer template is described below with reference to FIG. 2.

FIG. 2 shows a cross-sectional view of a first example semiconductor wafer template 200. In some examples, the semiconductor wafer template 200 is obtained in a pre-fabricated form, as a laminated structure of successively stacked layers: a substrate layer 202, an undoped GaN (u-GaN) buffer layer 204, a lower n-GaN layer 206, and a dielectric layer 208. In some examples, the semiconductor wafer template 200 is formed (or further formed) by growing the u-GaN buffer layer 204 on the substrate layer 202, growing the lower n-GaN layer 206 on the u-GaN buffer layer 204, and then depositing the dielectric layer 208 above the lower n-GaN layer 206.

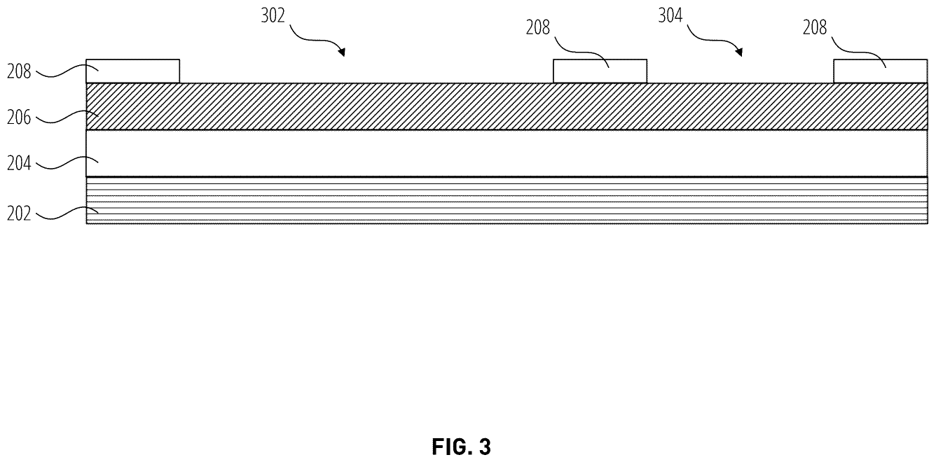

According to some examples, the method 100 includes forming first apertures 302 (as depicted in FIG. 3) through the dielectric layer 208 at operation 104. In some examples, the first apertures 302 are formed through selective etching using photolithography.

FIG. 3 shows a cross-sectional view of the semiconductor wafer template 200 after operation 104. The first aperture 302 and second aperture 304 may be formed through etching, such as wet etching, through the dielectric layer 208 to the lower n-GaN layer 206. In some examples, such as the illustrated example, the first aperture 302 may be formed at operation 104 in order to form a single mesa, and the second aperture 304 may be formed in order to form a single pyramid, as described below. However, it will be appreciated that the techniques described herein, with suitable modifications, may be suitable for LED pixel structures including one or more mesas and one or more pyramids.

In some examples, instead of having apertures formed by etching at operation 104, the dielectric layer 208 may instead be selectively deposited on the lower n-GaN layer 206 to include the first aperture 302 and second aperture 304.

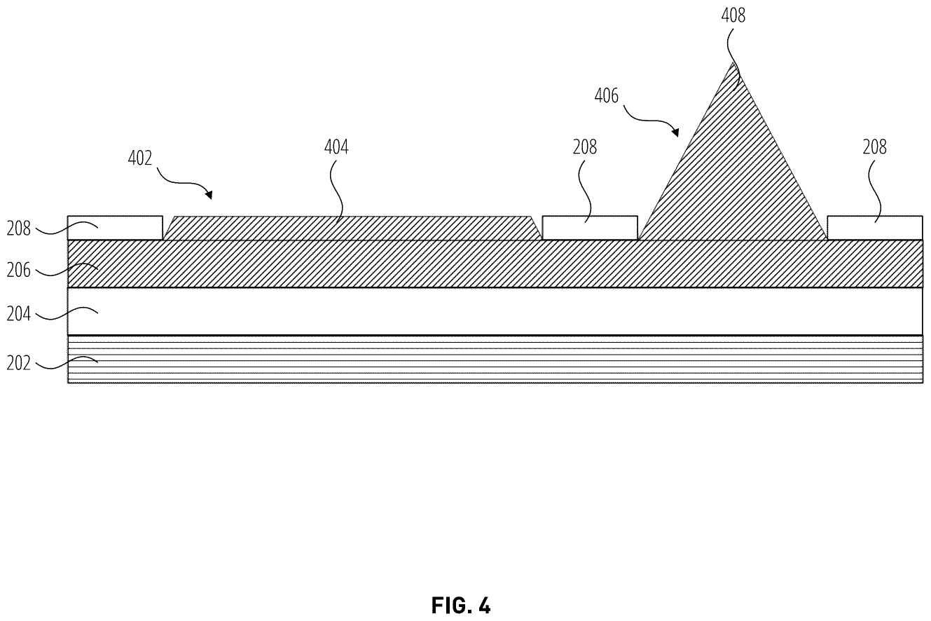

According to some examples, the method 100 includes growing a mesa n-GaN layer 404 in the first aperture 302 and growing a pyramidal n-GaN layer 408 in the second aperture 304 at operation 106 (as shown in FIG. 4). In some examples, the mesa n-GaN layer 404 and pyramidal n-GaN layer 408 may be formed through selective MOCVD overgrowth.

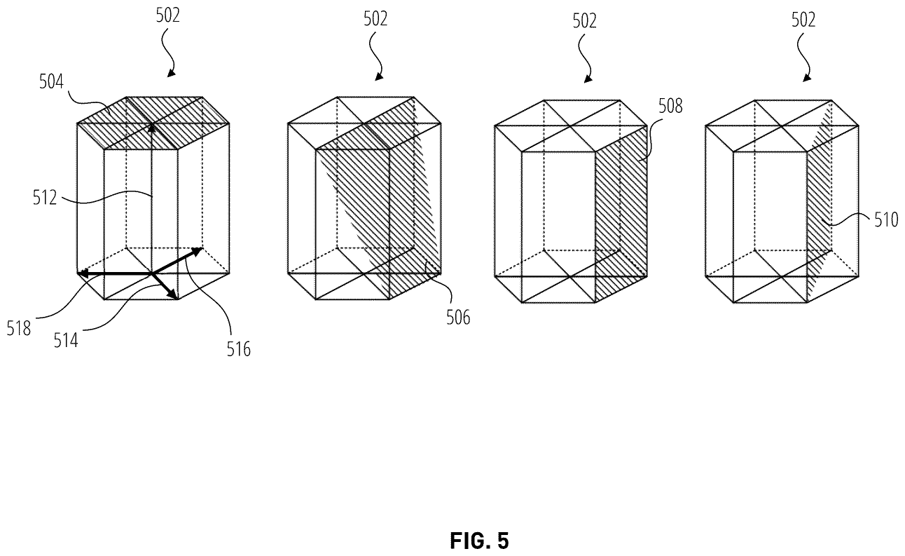

FIG. 4 shows a cross-sectional view of the semiconductor wafer template 200 after operation 106. In the illustrated example, a mesa n-GaN layer 404 is grown in the first aperture 302, forming a base of a mesa 402 within the first aperture 302, and the mesa n-GaN layer 404 functionally serves as an extension of the lower n-GaN layer 206. The sidewalls of the mesa 402 may be formed as a semi-polar surface of the GaN material used to form the mesa n-GaN layer 404, as described below with reference to FIG. 5.

Similarly, a pyramidal n-GaN layer 408 is grown in the second aperture 304, forming a pyramidal shape at the center of a pyramid 406 within the second aperture 304, and the pyramidal n-GaN layer 408 functionally serves as an extension of the lower n-GaN layer 206. The sidewalls of the pyramid 406 may be formed as a semi-polar surface of the GaN material used to form the pyramidal n-GaN layer 408, as described below with reference to FIG. 5.

FIG. 5 illustrates four different orientations of surfaces formed through a hexagonal crystal structure 502 of GaN material. The illustrated hexagonal crystal structure 502 characterizes GaN as well as various of its related ternary compounds such as indium gallium nitride (InGaN) and aluminum gallium nitride (AlGaN), all of which may be referred to herein as GaN materials.

The hexagonal crystal structure 502 of the GaN material defines several surface orientations that can be formed through the material. A polar (c-plane) surface 504, also referred to as the (0001) surface, defines a horizontal planar orientation normal to the c vector 512. A semi-polar surface 506, also referred to as the (10-11) surface, defines a diagonal planar orientation in which the plane intersects a top centerline of the hexagonal crystal structure 502 and one of the two bottom edges of the hexagonal crystal structure 502 parallel to the top centerline. A non-polar (m-plane) surface 508, also referred to as the (10-10) surface, defines a vertical planar orientation coplanar with one of the six sides of the hexagonal crystal structure 502. A non-polar (a-plane) surface 510, also referred to as the (11-20) surface, defines another vertical planar orientation extending from two nonadjacent top vertices of the hexagonal crystal structure 502 parallel to the c vector 512 contacting the two bottom vertex counterparts. The radial directions of the hexagonal crystal structure 502 are designated by the a1 vector 514, a2 vector 516, and a3 vector 518.

Thus, the sidewalls of the mesa 402 and pyramids 406 shown in FIG. 4 through FIG. 10 may be formed to extend diagonally from the mesa top or pyramid peak, at an angle defined by the semi-polar surface 506 of the hexagonal crystal structure 502 of the materials forming the mesa and pyramid. Specifically, the semi-polar surface 506 is at a 620 angle to the horizontal (e.g., the upper surface of the lower n-GaN layer 206). Thus, in some examples, the sidewalls of the mesa 402 and pyramid 406 may be sloped at a 62° angle.

According to some examples, the method 100 includes growing a superlattice 602 over the mesa n-GaN layer 404 at operation 108. The superlattice 602 may be grown as a periodic structure, such as alternating layers of indium gallium nitride (InGaN) and gallium nitride (GaN). The superlattice 602 may be grown as a layer or film having planar surfaces, using a deposition technique such as MOCVD. The superlattice 602 is configured to act as a strain relaxation layer for semiconductor materials grown on its top surface. In some examples, a superlattice may be grown on one or more sidewalls of the mesa 402 and/or the pyramid 406 as well as, or instead of, on the mesa top surface. In some examples, operation 108 may be omitted.

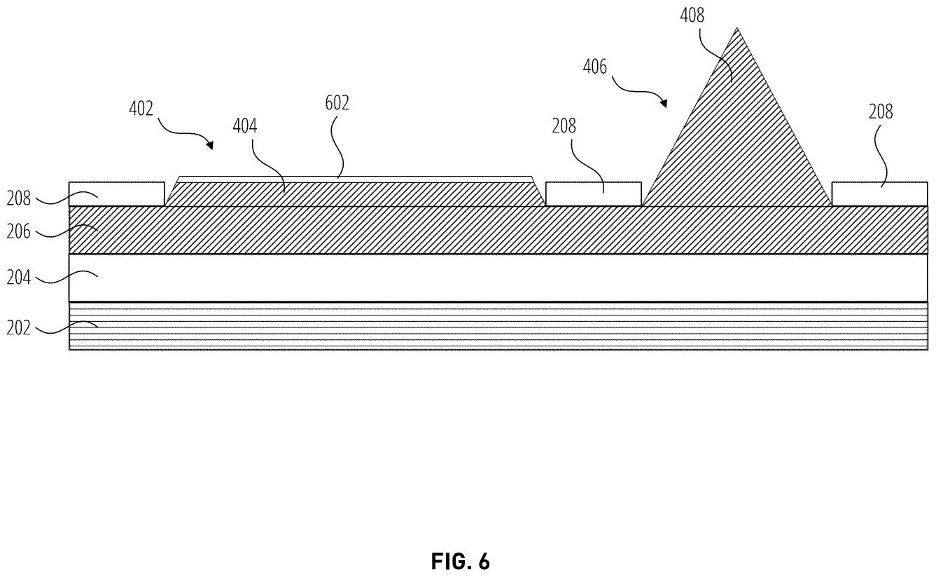

FIG. 6 shows a cross-sectional view of the semiconductor wafer template 200 after operation 108. The sidewalls of the mesa 402 may continue to align with the semi-polar surface 506 of the material of the superlattice 602, e.g., at a 62° angle to the surface of the lower n-GaN layer 206.

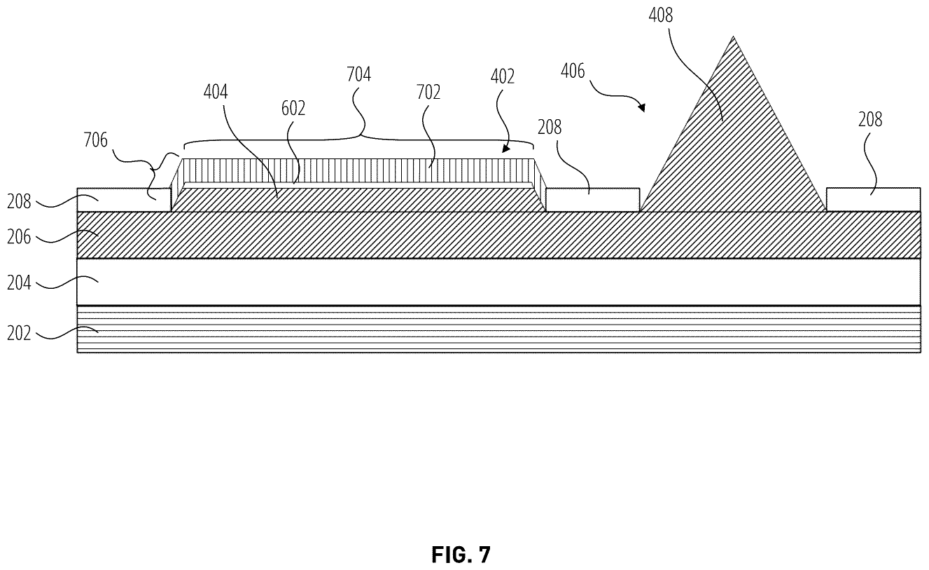

According to some examples, the method 100 includes growing a mesa MQW layer 702 (as shown in FIG. 7) over the superlattice 602 (or over the mesa n-GaN layer 404, if the superlattice 602 is omitted) at operation 110. In some examples, the mesa MQW layer 702 may be formed through epitaxy, with growth conditions optimized for the specific MQW type (e.g., LED color) being grown.

FIG. 7 illustrates a cross-sectional view of the semiconductor wafer template 200 after the growth of the mesa MQW layer 702 during operation 110. The mesa MQW layer 702 is grown over the mesa top and sidewalls of the mesa 402, thereby defining a mesa top portion 704 and a mesa sidewall portion 706, respectively, of the mesa MQW layer 702. The sidewalls of each mesa 402 may continue to align with the semi-polar surface 506 of the GaN material of the mesa MQW layer 702, e.g., at a 62° angle to the surface of the lower n-GaN layer 206.

In some examples, the mesa MQW layer 702 is configured to emit a single color of light (e.g., red light), or to be tunable between two wavelengths of light by modulating a current stimulus (e.g., tunable between red and green light). In some examples, the mesa top portion 704 is configured to emit a first color of light (e.g., red light), and the mesa sidewall portions 706 are configured to emit a second color of light (e.g., green light). It will be appreciated that other combinations of single-light and/or tunable-light configurations can be used for the mesa top portion 704 and/or the mesa sidewall portions 706.

According to some examples, the method 100 includes forming a pyramidal MQW layer 802 above the pyramidal n-GaN layer 408, also at operation 110. In some examples, the pyramidal MQW layer 802 may be formed through epitaxy, with growth conditions optimized for the specific MQW type (e.g., LED color) being grown. The pyramidal MQW layer 802 may be grown simultaneously with, or separate from, the mesa MQW layer 702; in examples using different colors for the mesa MQW layer 702 and pyramidal MQW layer 802, it may be advantageous to grow each separately, under conditions optimized for the MQW type being grown on each structure.

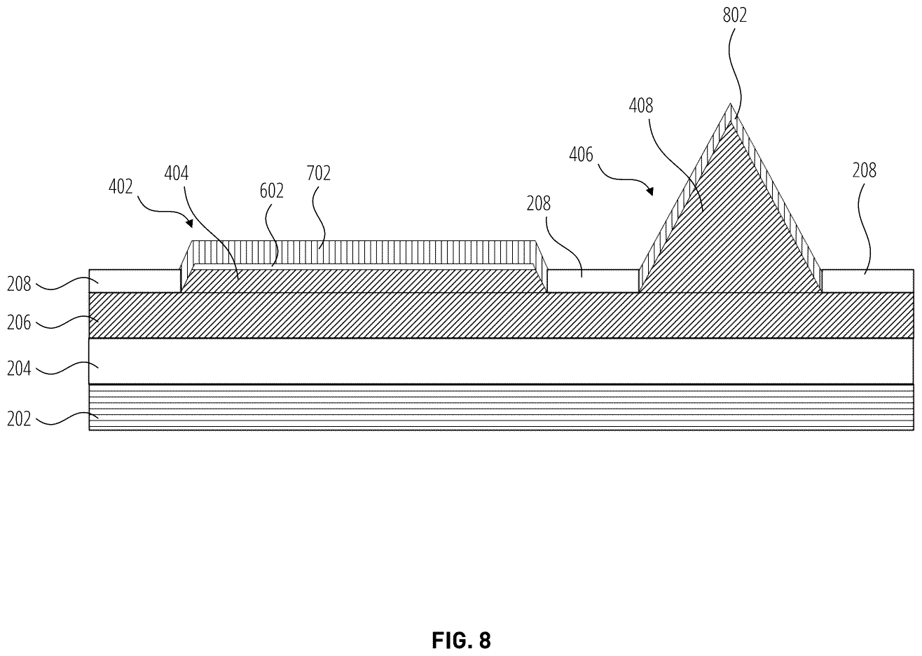

FIG. 8 illustrates a cross-sectional view of the semiconductor wafer template 200 after operation 110. The pyramidal MQW layer 802 is grown on the sidewalls of the pyramid 406.

As described above, the pyramidal MQW layer 802 may be thinner than the mesa top portion 704 of the mesa MQW layer 702 due to growth on the semi-polar sidewalls of the pyramid 406, potentially resulting in a blue shift in the color of light emitted by the pyramidal MQW layer 802 relative to the mesa top portion 704 of the mesa MQW layer 702. Thus, in some examples, the pyramidal MQW layer 802 may be configured to emit blue light, or light tunable between blue and green based on modulation of an electrical current stimulus.

According to some examples, the method 100 includes forming an electron blocking layer 902 over the mesa MQW layer 702 and/or the pyramidal MQW layer 802 at operation 112. The electron blocking layer 902 may enhance the efficiency of the mesa LED and/or pyramid LED by reducing electron overflow and improving hole injection into the MQW layer of each LED. The electron blocking layer 902 may be formed using a deposition technique such as MOCVD overgrowth. In some examples, operation 112 may be omitted.

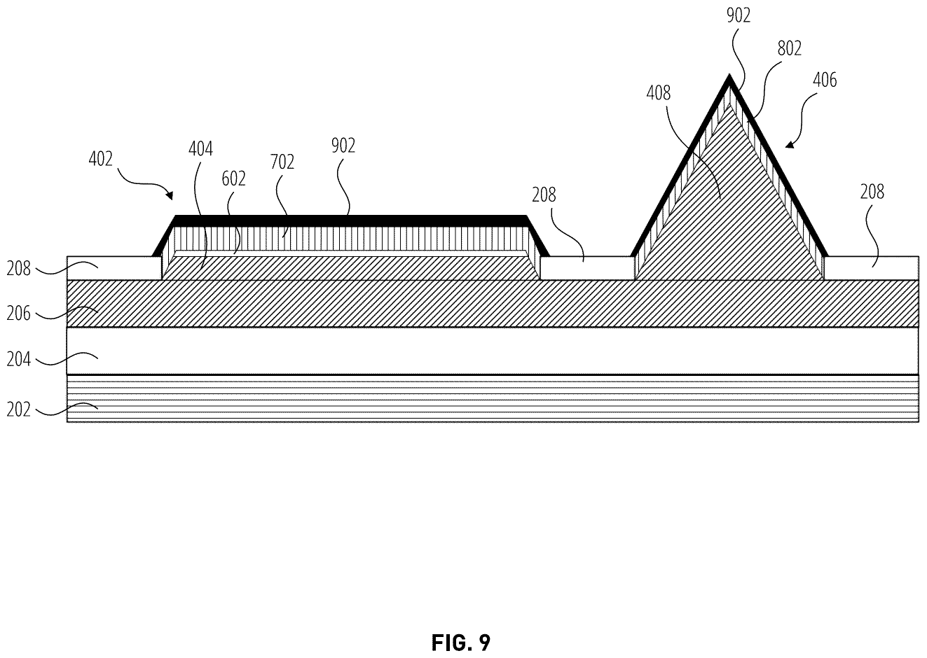

FIG. 9 shows a cross-sectional view of the semiconductor wafer template 200 after operation 112. An electron blocking layer 902 is formed over the mesa MQW layer 702, and another electron blocking layer 902 is formed over the pyramidal MQW layer 802. The electron blocking layers 902 may be formed from any suitable material for forming an electron blocking layer, such as a magnesium-doped p-type AlGaN having a high aluminum composition. In some examples, this operation may be omitted; the electron blocking layer 902 is optional for both the mesa 402 and the pyramid 406.

According to some examples, the method 100 includes forming a mesa p-GaN layer 1002 (as shown in FIG. 10) and a pyramidal p-GaN layer 1004 at operation 114. The mesa p-GaN layer 1002 and pyramidal p-GaN layer 1004 may be formed using a deposition technique such as MOCVD overgrowth.

FIG. 10 shows a cross-sectional view of the semiconductor wafer template 200 after operation 114, providing a pixel structure 1000. A mesa p-GaN layer 1002 has been formed over the top and sidewalls of the mesa 402, and a pyramidal p-GaN layer 1004 has been formed over the sidewalls of the pyramid 406.

The mesa p-GaN layer 1002, mesa MQW layer 702, and mesa n-GaN layer 404 jointly form (optionally with the electron blocking layer 902, superlattice 602, and/or lower n-GaN layer 206) a mesa LED, configured to emit light from the mesa MQW layer 702 when stimulated by an electrical current applied between the n-GaN material (e.g., lower n-GaN layer 206 and/or mesa n-GaN layer 404) and the p-GaN material (e.g., mesa p-GaN layer 1002). This stimulus may be applied via one or more electrical contacts formed on various surfaces of the mesa 402 and/or nearby layers of the pixel structure 1000. In some examples, one or more p-type electrical contacts (also called p-contacts) may be formed on one or more surfaces of the mesa p-GaN layer 1002; these p-contacts may be formed from a suitable conductive material for forming an electrical contact on a p-GaN material, such as gold, a gold alloy, or a transparent conductive oxide, e.g., indium tin oxide (ITO). In some examples, one or more n-type electrical contacts (also called n-contacts) may be formed on one or more surfaces of the lower n-GaN layer 206 and/or mesa n-GaN layer 404; for example, one or more remaining portions of the dielectric layer 208 may be removed (e.g., by wet etching, to prevent damage to the GaN layers), and one or more n-contacts may be formed on the exposed portions of the lower n-GaN layer 206. These n-contacts may be formed from suitable conductive materials for forming an electrical contact on an n-GaN material, such as aluminum or an aluminum-containing compound or alloy.

In other examples, the entire mesa MQW layer 702 is stimulated by a single stimulus via a single pair of contacts, to function as a single mesa LED. In some examples, the mesa top portion 704 and mesa sidewall portions 706 may be stimulated separately, via separate p-contacts and/or n-contacts, in order to independently modulate an amount of light emitted by the mesa top portion 704 and by the mesa sidewall portions 706 of the mesa MQW layer 702, to function as two or more mesa LEDs (e.g., a mesa top LED and a mesa sidewall LED).

Similarly, the pyramidal p-GaN layer 1004, pyramidal MQW layer 802, and pyramidal n-GaN layer 408 jointly form (optionally with the electron blocking layer 902 and/or lower n-GaN layer 206) a pyramid LED, configured to emit light from the pyramidal MQW layer 802 when stimulated by an electrical current applied between the n-GaN material (e.g., lower n-GaN layer 206 and/or pyramidal n-GaN layer 408) and the p-GaN material (e.g., pyramidal p-GaN layer 1004). This stimulus may be applied via one or more electrical contacts formed on various surfaces of the pyramid 406 and/or nearby layers of the pixel structure 1000. A p-contact may be formed on the pyramidal p-GaN layer 1004, and as in the case of the mesa LED, an n-contact may be formed on an exposed portion of the lower n-GaN layer 206 exposed by wet etching. It will be appreciated that various configurations of electrical contacts may be used to independently stimulate the emission of light by the mesa MQW layer 702 and pyramidal MQW layer 802, and optionally by the mesa top portion 704 and mesa sidewall portions 706 of the mesa MQW layer 702.

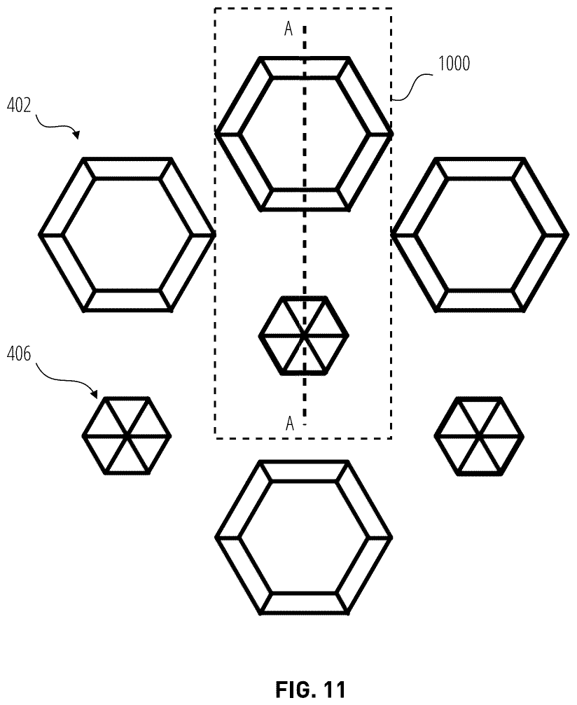

FIG. 11 illustrates an overhead view of an LED pixel array including multiple tiled pixel structures 1000 of FIG. 10. The cross-sectional view of FIG. 10 can be regarded as being a view through cross-sectional line A-A shown in FIG. 11.

In the illustrated example LED pixel array layout, the mesa 402 has six sidewalls, defining a substantially hexagonal shape of the mesa 402. Similarly, each pyramid 406 also has six sidewalls, defining a substantially hexagonal shape of the pyramid 406. The mesas 402 and pyramids 406 are laid out to form a honeycomb or hexagonal grid layout. Thus, a mesa 402 and a pyramid 406 may be regarded as forming a single pixel structure 1000, as shown in dashed outline.

It will be appreciated that the layout shown in FIG. 11 may constitute only a small portion of the entire LED pixel array, which may include hundreds, thousands, or millions of pixel structures 1000 in some examples.

In some examples, a different overhead shape may be used for the mesas 402 and/or pyramids 406, and/or the mesas 402 and pyramids 406 may be laid out in a different pattern.

However, the hexagonal crystal structure 502 of the mesa MQW layer 702, superlattice 602, and mesa n-GaN layer 404 may facilitate the formation of mesas 402 having a hexagonal shape such as that illustrated in FIG. 11.

In some examples, the various structures shown and described herein have dimensions configured for the formation of microLED pixels. In a first example, the lower n-GaN layer 206 has a thickness of approximately between several hundred nanometers (nm) and a few (e.g., fewer than ten) microns (micrometers, m). The height of the mesa 402 depends on the total thickness of the MOCVD overgrowth, so the range of mesa height is approximately between 100 nm to a few (e.g., <10) microns. Mesa width, pyramid width, and pixel pitch can be selected in accordance with a desired pixels per inch (PPI) specification for the pixel array; in various examples, the mesa width can be between tens of nm to several hundred microns.

### CONCLUSION

LED pixel arrays, and methods for fabricating same, are described herein in reference to various examples. Some examples may maximize the amount of red light emitted by the pixel structure 1000 by configuring the mesa top portion 704 and mesa sidewall portion 706 of the mesa MQW layer 702 to all emit red light, and configuring the pyramidal MQW layer 802 to be tunable between blue and green light. Some examples may configure the mesa MQW layer 702 as a tunable red/green MQW layer, or may configure the mesa top portion 704 as a red MQW layer and the mesa sidewall portions 706 as a green MQW layer, while the pyramid LED is configured as a blue LED. It will be appreciated that other configurations can be used in different examples to achieve different desired effects.

Example 1 is a method of fabricating a light emitting diode (LED) pixel array from a semiconductor wafer template comprising a dielectric layer formed over a lower n-type gallium nitride (n-GaN) layer, the method comprising: forming a first aperture and a second aperture through the dielectric layer and extending to the lower n-GaN layer, the second aperture being narrower than the first aperture; forming a mesa within the first aperture by successively forming: a mesa n-GaN layer; a mesa MQW layer above the mesa n-GaN layer; and a mesa p-GaN layer above the mesa MQW layer; and forming a pyramid within the second aperture by successively forming: a pyramidal n-GaN layer having sidewalls; a pyramidal MQW layer over the sidewalls of the pyramidal n-GaN layer; and a pyramidal p-GaN layer over the pyramidal MQW layer; such that: the mesa n-GaN layer, mesa MQW layer, and mesa p-GaN layer forms a mesa LED; and the pyramidal n-GaN layer, pyramidal MQW layer, and pyramidal p-GaN layer form a pyramid LED.

In Example 2, the subject matter of Example 1 includes, forming a superlattice above the mesa n-GaN layer and beneath the mesa MQW layer.

In Example 3, the subject matter of Example 2 includes, wherein: the superlattice comprises a periodic structure comprising alternating layers of indium gallium nitride (InGaN) and gallium nitride (GaN).

In Example 4, the subject matter of Examples 2-3 includes, wherein: the mesa LED is a tunable red/green LED.

In Example 5, the subject matter of Examples 1-4 includes, wherein: the mesa LED is a red LED.

In Example 6, the subject matter of Examples 1-5 includes, wherein: the mesa has sidewalls; and the sidewalls of the mesa and the sidewalls of the pyramid are formed at an angle defined by a semi-polar surface of a crystal structure of the mesa and the pyramid.

In Example 7, the subject matter of Examples 1-6 includes, wherein: the pyramidal MQW layer is configured to emit light having a shorter wavelength than light emitted by the mesa MQW layer.

In Example 8, the subject matter of Example 7 includes, wherein: the pyramid LED is a blue LED; and the mesa LED is a tunable red/green LED.

In Example 9, the subject matter of Examples 7-8 includes, wherein: the pyramid LED is a tunable blue/green LED; and the mesa LED is a red LED.

In Example 10, the subject matter of Examples 7-9 includes, wherein: the mesa MQW layer comprises: a mesa top portion configured to emit red light; and a mesa sidewall portion configured to emit green light.

In Example 11, the subject matter of Examples 7-10 includes, wherein: the pyramidal MQW layer is thinner than the mesa MQW layer.

In Example 12, the subject matter of Examples 7-11 includes, wherein: the pyramidal MQW layer has a weaker quantum confined stacking effect than the mesa MQW layer.

In Example 13, the subject matter of Examples 1-12 includes, forming an electron blocking layer above the mesa MQW layer.

In Example 14, the subject matter of Examples 1-13 includes, forming an electron blocking layer above the pyramidal MQW layer.

In Example 15, the subject matter of Examples 1-14 includes, wherein: the semiconductor wafer template further comprises, under the lower n-GaN layer, an undoped gallium nitride (u-GaN) layer above a substrate layer.

In Example 16, the subject matter of Examples 1-15 includes, wherein: the mesa has six sidewalls, defining a substantially hexagonal shape of the mesa.

In Example 17, the subject matter of Examples 1-16 includes, wherein: the pyramid has six sidewalls, defining a substantially hexagonal shape of the pyramid.

Example 18 is a pixel array formed in accordance with the method of Example 1.

Example 19 is a light emitting diode (LED) pixel array, comprising a plurality of LED pixel structures, each LED pixel structure comprising: a mesa formed above a lower p-GaN layer, defining a mesa LED comprising a mesa n-GaN layer, a mesa MQW layer, and a mesa p-GaN layer; and a pyramid LED formed above the lower p-GaN layer, defining a pyramid LED comprising a pyramidal n-GaN layer, a pyramidal MQW layer, and a pyramidal p-GaN layer.

In Example 20, the subject matter of Example 19 includes, wherein: the mesa MQW layer comprises: a mesa top portion configured to emit red light; and a mesa sidewall portion configured to emit green light; and the pyramidal MQW layer is configured to emit blue light.

Example 21 is at least one machine-readable medium including instructions that, when executed by processing circuitry, cause the processing circuitry to perform operations to implement of any of Examples 1-20.

Example 22 is an apparatus comprising means to implement any of Examples 1-20.

Example 23 is a system to implement any of Examples 1-20.

Example 24 is a method to implement any of Examples 1-20.

Other technical features and/or benefits may be readily apparent to one skilled in the art from the figures, descriptions, and claims herein.

What is claimed is:

1. A method of fabricating a light emitting diode (LED) pixel array from a semiconductor wafer template comprising a dielectric layer formed over a lower n-type gallium nitride (n-GaN) layer, the method comprising:
forming a first aperture and a second aperture through the dielectric layer and extending to the lower n-GaN layer, the second aperture being narrower than the first aperture;
forming a mesa within the first aperture by successively forming:
a mesa n-GaN layer;
a mesa MQW layer above the mesa n-GaN layer; and
a mesa p-GaN layer above the mesa MQW layer; and
forming a pyramid within the second aperture by successively forming:
a pyramidal n-GaN layer having sidewalls;
a pyramidal MQW layer over the sidewalls of the pyramidal n-GaN layer; and
a pyramidal p-GaN layer over the pyramidal MQW layer;
such that:
the mesa n-GaN layer, mesa MQW layer, and mesa p-GaN layer form a mesa LED; and
the pyramidal n-GaN layer, pyramidal MQW layer, and pyramidal p-GaN layer form a pyramid LED.

2. The method of claim 1, further comprising:
forming a superlattice above the mesa n-GaN layer and beneath the mesa MQW layer.

3. The method of claim 2, wherein:
the superlattice comprises a periodic structure comprising alternating layers of indium gallium nitride (InGaN) and gallium nitride (GaN).

4. The method of claim 2, wherein:
the mesa LED is a tunable red/green LED.

5. The method of claim 1, wherein:
the mesa LED is a red LED.

6. The method of claim 1, wherein:
the mesa has sidewalls; and
the sidewalls of the mesa and the sidewalls of the pyramid are formed at an angle defined by a semi-polar surface of a crystal structure of the mesa and the pyramid.

7. The method of claim 1, wherein:
the pyramidal MQW layer is configured to emit light having a shorter wavelength than light emitted by the mesa MQW layer.

8. The method of claim 7, wherein:
the pyramid LED is a blue LED; and
the mesa LED is a tunable red/green LED.

9. The method of claim 7, wherein:
the pyramid LED is a tunable blue/green LED; and
the mesa LED is a red LED.

10. The method of claim 7, wherein:
the mesa MQW layer comprises:
a mesa top portion configured to emit red light; and
a mesa sidewall portion configured to emit green light.

11. The method of claim 7, wherein:
the pyramidal MQW layer is thinner than the mesa MQW layer.

12. The method of claim 7, wherein:
the pyramidal MQW layer has a weaker quantum confined stacking effect than the mesa MQW layer.

13. The method of claim 1, further comprising:
forming an electron blocking layer above the mesa MQW layer.

14. The method of claim 1, further comprising:
forming an electron blocking layer above the pyramidal MQW layer.

15. The method of claim 1, wherein:
the semiconductor wafer template further comprises, under the lower n-GaN layer, an undoped gallium nitride (u-GaN) layer above a substrate layer.

16. The method of claim 1, wherein:
the mesa has six sidewalls, defining a substantially hexagonal shape of the mesa.

17. The method of claim 1, wherein:
the pyramid has six sidewalls, defining a substantially hexagonal shape of the pyramid.

18. A pixel array formed in accordance with the method of claim 1.

19. A light emitting diode (LED) pixel array, comprising a plurality of LED pixel structures, each LED pixel structure comprising:
a mesa formed above a lower p-GaN layer, defining a mesa LED comprising a mesa n-GaN layer, a mesa MQW layer, and a mesa p-GaN layer; and
a pyramid LED formed above the lower p-GaN layer, defining a pyramid LED comprising a pyramidal n-GaN layer, a pyramidal MQW layer, and a pyramidal p-GaN layer.

20. The pixel array of claim 19, wherein:
the mesa MQW layer comprises:
a mesa top portion configured to emit red light; and
a mesa sidewall portion configured to emit green light; and
the pyramidal MQW layer is configured to emit blue light.
